(19) United States
(12) Patent Application Publication
(10) Pub. No.: US 2026/0284902 A1
(43) Pub. Date: Sep. 24, 2026

(54) FLEXIBLE PRESSURE SENSORS, ROBOT HANDS, AND METHODS OF FABRICATION

(71) Applicant: Purdue Research Foundation, West Lafayette, IN (US)

(72) Inventors: Sunghwan Lee, West Lafayette, IN (US); Huachao Mao, West Lafayette, IN (US); Jinwook Baek, West Lafayette, IN (US); Yujie Shan, West Lafayette, IN (US)

(21) Appl. No.: 19/473,018

(22) PCT Filed: Apr. 12, 2024
(86) PCT No.: PCT/US2024/024250

§ 371 Date: Oct. 6, 2025

Related U.S. Application Data
(60) Provisional application No. 63/458,832, filed on Apr. 12, 2023.

(51) Int. Cl. B25J 13/08; B25J 15/00

(52) U.S. Cl. CPC B25J 13/084; B25J 15/0009

(57) ABSTRACT

Flexible pressure sensors, robot hands, and methods of fabrication. Such a flexible pressure sensor includes a substrate layer having of a plurality of 3D printed layers, and a sensing element layer including a conductive conjugated polymer conformally coated on an exterior surface of the substrate layer. Pressure induced deformations of the exterior surface layer cause detectable changes in electrical current applied across the sensing element layer. In one method, a flexible pressure sensor may be fabricated by forming a substrate layer by additive manufacturing, and then conformally coating the substrate layer with a conjugated polymer by oxidative chemical vapor deposition. The substrate layer may have a plurality of protrusions extending from a base surface. The protrusions may be single-scale sensor protrusions or multiscale sensor protrusions. A robot hand may incorporate the flexible pressure sensor.

### CROSS-REFERENCE TO RELATED APPLICATIONS

This application claims the benefit of provisional U.S. Patent Application No. 63/458,832 filed Apr. 12, 2023, the contents of which are incorporated herein by reference.

### STATEMENT REGARDING FEDERALLY SPONSORED RESEARCH

This invention was made with government support under CBET-2207302 awarded by the National Science Foundation. The government has certain rights in the invention.

### BACKGROUND OF THE INVENTION

The present invention generally relates to pressure sensors. The invention particularly relates to flexible pressure sensors and the fabrication thereof, as well as robot hands that incorporate flexible pressure sensors.

Flexible pressure sensors have drawn wide attention because of their potential applications in electronic skin, soft robotics, and healthcare monitoring. Among the various types of sensors employing piezoresistive, capacitive, piezoelectric, and triboelectric sensing mechanisms, the piezoresistive type pressure sensors have been consistently studied due to their simple structures and high sensitivity resulting in promising commercialization prospects. However, critical limitations of existing pressure sensors lead to lower sensing performance and hinder the wider adoption of pressure sensors in practical robots and advanced healthcare sectors. First, most pressure sensors are only sensitive to a narrow range of pressure, but insensitive beyond that range. Hence, current pressure sensors can detect either low pressure induced by soft objects (e.g., hair), or high pressure induced by stiff objects (e.g., metal spoon), but not both. Second, most pressure sensors have limited geometry and flexibility, restricting sensors from being placed on heavily deformable and curved surfaces, such as the joints of a robotic hand or a conical fingertip.

Micropatterned structures on flexible substrates show promise to address the above issues, by utilizing geometric patterns to increase the contact area. To date, the micropatterned structures are typically created by a Silicon/Anodic Aluminum Oxide (AAO) mold with micro patterns and shapes on a flexible substrate (e.g., polydimethylsiloxane (PDMS)). However, such a mold-based manufacturing approach did not fully unleash the potential of micropatterned structures. It can only fabricate simple micropatterns, such as pyramids, domes, and conical frustum, due to a series of tedious patterning processes, including photo- or electron-beam lithographical steps with mask alignment and multiple deep dry etching processes. Pressure sensors with such simple micropatterns, although manufactured through not-simple processes, become less sensitive to a large pressure, which reduces the usage in a wide range of pressure. More importantly, the coated sensing elements are restricted to thick solution-processed polymers or brittle inorganic materials. Such brittle and thick coating, in turn, excludes hierarchically-patterned (i.e., multiscale) structures, because thick coatings will cover and smoothen out the microscale features and brittle materials will be delaminated from the flexible substrates or failed through repeated cycles of pressure applications and bending.

Therefore, it would be desirable to have flexible pressure sensors that have a wider range of sensitivity.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, flexible pressure sensors, methods of fabricating flexible pressure sensors, and robot hands that incorporate flexible pressure sensors.

According to a nonlimiting aspect, a flexible pressure sensor includes a substrate layer having of a plurality of three-dimensional (3D) printed layers, and a sensing element layer including a conductive conjugated polymer conformally coated on an exterior surface of the substrate layer. Pressure induced deformations of the exterior surface layer cause detectable changes in electrical current applied across the sensing element layer.

According to another nonlimiting aspect, a method of fabricating a flexible pressure sensor is provided. Them method includes printing, by additive manufacturing, a substrate layer comprising a plurality of protrusions extending from a base surface, and conformally coating, by oxidative chemical vapor deposition, the substrate layer with a conjugated polymer.

According to still another nonlimiting aspect, a robot hand includes a flexible pressure sensor as described above mounted to a robotic hand.

Technical aspects of flexible pressure sensors, methods, and robot hands as described above preferably include the capability of a pressure sensor to have a wider range of sensitivity than conventional pressure sensors and/or facilitate the design and adaptation of a pressure sensor for a wide range of use scenarios that require sensing characteristics.

These and other aspects, arrangements, features, and/or technical effects will become apparent upon detailed inspection of the figures and the following description.

### BRIEF DESCRIPTION OF THE DRAWINGS

FIG. 1A is a perspective view of a flexible pressure sensor according to a first embodiment of the invention having single-scale sensor protrusions that have dome shapes.

FIG. 1B is a perspective view of a flexible pressure sensor according to a second embodiment of the invention having multiscale sensor protrusions that have dome shapes and low-density spike arrays on each dome.

FIG. 1C is a perspective view of a flexible pressure sensor according to a third embodiment of the invention having multiscale sensor microstructures that have dome shapes and high-density spike arrays on each dome.

FIG. 1D is an enlarged perspective view of a multiscale sensor protrusion of the pressure sensor of FIG. 1C.

FIG. 2 is a cross-sectional view through a multiscale sensor microstructure of the pressure sensor of FIG. 1B.

FIGS. 3A through 3C illustrate stages in a process of fabricating the flexible pressure sensors according to another nonlimiting embodiment of the invention.

FIGS. 3D and 3E represent testing results from investigations of flexible pressure sensors fabricated with the method of FIGS. 3A-3C.

FIG. 4A is an SEM image of an as-printed DHSA flexible pressure sensor and an enlarged SEM image from the navy box. The scale bar is 500 μm and 10 μm for left and right images.

FIG. 4B is a schematic representation of the cross-section of the multiscale sensor protrusion with features across three size scales, namely, millimeter, sub-millimeter, and micrometer scale sizes.

FIG. 4C is a graph of the contact area changes with the pressure for a structure with a DHSA, DLSA, and dome variations of the multiscale sensor protrusion.

FIG. 4D illustrates deformation and stress distribution of the multiscale sensor protrusion under different pressures calculated by FEA.

FIG. 4E is a cross-section view of the multiscale sensor protrusion under pressure. A printed spike has layer stepping defects on its surface.

FIGS. 4F and 4G illustrate stress distribution (FIG. 4F) and contact area (FIG. 4G) for different local pressure.

FIG. 4H is a graph that shows contact area with the local pressure applied to the spike surface. Printed spikes with stairs have 57.8% more contact area than smooth spikes.

FIG. 5A is an image of image of the flexible pressure sensor attached to the fingertips of a robot hand.

FIG. 5B is an image of flexible pressure sensor mounted on a human finger joint.

### DETAILED DESCRIPTION OF THE INVENTION

The intended purpose of the following detailed description of the invention and the phraseology and terminology employed therein is to describe what is shown in the drawings, which include the depiction of and/or relate to one or more nonlimiting embodiments of the invention, and to describe certain but not all aspects of the embodiment(s) to which the drawings relate. The following detailed description also describes certain investigations relating to the embodiment(s) depicted in the drawings, and identifies certain but not all alternatives of the embodiment(s) depicted in the drawings. As nonlimiting examples, the invention encompasses additional or alternative embodiments in which one or more features or aspects shown and/or described as part of a particular embodiment could be eliminated, and also encompasses additional or alternative embodiments that combine two or more features or aspects shown and/or described as part of different embodiments. Therefore, the appended claims, and not the detailed description, are intended to particularly point out subject matter regarded to be aspects of the invention, including certain but not necessarily all of the aspects and alternatives described in the detailed description.

To facilitate the description provided below of the embodiment(s) represented in the drawings, relative terms, including but not limited to, “proximal,” “distal,” “anterior,” “posterior,” “vertical,” “horizontal,” “lateral,” “front,” “rear,” “side,” “forward,” “rearward,” “top,” “bottom,” “upper,” “lower,” “above,” “below,” “right,” “left,” etc., may be used in reference to the orientation of the flexible pressure sensor during its use and/or as represented in the drawings. All such relative terms are useful to describe the illustrated embodiment(s) but should not be otherwise interpreted as limiting the scope of the invention.

As used herein the terms “a” and “an” to introduce a feature are used as open-ended, inclusive terms to refer to at least one, or one or more of the features, and are not limited to only one such feature unless otherwise expressly indicated. Similarly, use of the term “the” in reference to a feature previously introduced using the term “a” or “an” does not thereafter limit the feature to only a single instance of such feature unless otherwise expressly indicated.

This application discloses a flexible pressure sensor that is preferably capable of being produced by way of mold-free fabrication. According to various embodiments, the fabrication may utilize high-resolution three-dimensional (3D) printing and conformal coating of conducting polymer films. By way of example, the flexible pressure sensor may include a substrate layer having a plurality of 3D printed layers. The substrate layer may a multiscale structure. The multiscale structure may include, for example, a first protrusion extending off of a substantially flat surface and one or more second protrusions extending from the first protrusion. The flexible pressure sensor may further include a sensing element layer coated over an exterior surface of the substrate layer at the protrusions. The sensing element layer may include a conductive conjugated polymer conformally coated on the substrate layer.

In comparison to conventional micropatterning with mold-based manufacturing, 3D printing is advantageous in terms of process simplification and efficiency since it excludes the complicated mold-based manufacturing process while achieving the target pressure range of a pressure sensor. However, studies on 3D printing-based pressure sensors are limited because the printing technique with a resolution comparable to photolithography has not yet been established. Extrusion-based 3D printing processes are commonly used to fabricate functional sensors and 3D printed molds by replacing Si, due to the easy deposit of multiple materials. However, the resolution of extrusion-based 3D printing is determined by the nozzle size, which is typically larger than 100 μm. Some techniques are utilized to refine the printed feature size, such as electrohydrodynamic (EHD) or finer nozzle size. Inkjet printing utilizes an array of nozzles but is typically limited to non-viscous materials. Among all 3D printing techniques, vat photopolymerization (VPP) has recently achieved a high feature resolution. A variety of functional materials can be processed using the VPP process, including the flexible photo-curable resin. Although VPP has an inherent drawback of the tradeoff between the resolution and printing volume, there are ways to increase the resolution and printing volume, coined large area high-resolution 3D printing.

According to various approaches described herein, liquid crystal display (LCD)-based VPP may be leveraged to manufacture the pressure sensor's substrate with a multiscale pattern, which is then seamlessly coated with a nanoscale sensing element using gas-phase conductive polymer coating. Oxidative chemical vapor deposition (oCVD) technique coats a nanoscale poly (3,4-ethylenedioxythiophene) (PEDOT) layer on the 3D-printed microstructure pattern with excellent step coverages, mechanical flexibility, and tunable conductivity. In contrast, conventional solution processing of polymers cannot make full use of the intended benefits of 3D-printed multiscale structures due to its non-conformal coating nature. In investigations of the flexible pressure sensors disclosed herein, the uniformity of the 3D-printed substrate and PEDOT film were confirmed by scanning electron microscope (SEM) analysis. The sensor characteristics were measured in accordance with the density and distribution of small features in order to assess the effect of the microstructure, and the finite element analysis (FEA) simulation supported the experimental results. Finally, the sensor was attached around the fingertip of the robot hand 26 to demonstrate the potential use of our pressure sensor in practical applications.

Accordingly, a technical advancement provided by the flexible pressure sensors and method of fabricating them is to exclude any mold-based processes (e.g., lithographical patterning and layer transfer) while further enhancing the benefits of the mold (i.e., larger contact area) in a facile manner. To this end, two manufacturing approaches are synergistically leveraged. First, multiscale patterns featuring three different dimensions (10 μm to 1 mm) are realized through high-resolution 3D printing. Second, the intended multiscale patterns need to be preserved after the coating of flexible sensing elements, which is often limited by conventional solution processing due to the lack of conformality and thickness controllability. The highly conformal and flexible polymer coating with optimized thickness is achieved through the vapor-phase oCVD polymer technique.

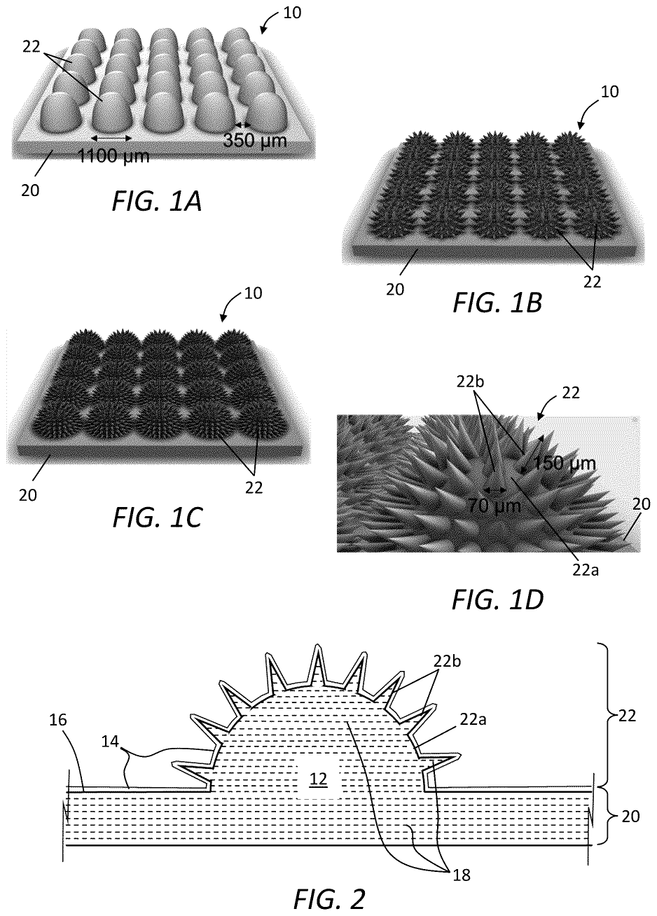

Turning now to the nonlimiting embodiments represented in the drawings, FIGS. 1A-1D depict three different embodiments of a flexible pressure sensor 10 according to certain aspects of the invention. As best seen in FIG. 2, each pressure sensor 10 has a flexible substate layer 12 that is fabricated by additive manufacturing, and specifically by 3D printing and a sensing element layer 14 coated on an exterior surface 16 of the substrate layer. The substrate layer 12 is formed of large number of individual 3D printed layers 18 of a printable resilient flexible material that, together, define the overall size and exterior shape of the substrate layer. In some preferred embodiments, the substrate layer is formed of 3D printed polydimethylsiloxane (PDMS), but other types of silicon elastomers or other similar printable flexible polymeric materials may be used. For example, the performance of a piezoresistive pressure sensor depends on the areal variation of conductive paths with applied pressure, which is determined by the contact area between the responsive sensing element and the electrode. The goal is to achieve a consistent increase in contact area without reaching a saturation point. This increase should ideally follow a linear pattern, dependent on the deformation properties related to the mechanical strength of the materials involved. When utilizing 3D printing, it becomes possible to control the mechanical strength of microstructures of sensor material through the selection or mixing of several printing materials and optimizing curing/post-curing conditions. This freedom of material selection, depending on the requirements, addresses the issues found in conventional mold-based and PDMS-dependent manufacturing that often limit the sensing range. To investigate the effect of the mechanical strength of 3D printing materials on the sensing range, pressure sensors were manufactured with three different mechanical property resins (Resin A, Resin B, Resin C) where the mechanical properties were engineered by discriminating resin compositions and post-curing conditions. The mechanical properties of each resin were verified by systematic compressive tests. The Young's modulus, which is a measure of stiffness, of the engineered A, B, and C resins was estimated to be 0.8, 5.7, and 6.8 kPa, respectively, while strain, a measure of deformation, is maximized with the Resin A and is least with the Resin C. From this, it is expected that enhanced linear sensing behavior may be achieved from the Resin A, which demonstrates better deformability and hence potentially the larger contact area between the printed substrate and electrode. As a result, the effect of pressure-induced deformation on sensor characteristics can be determined based on the mechanical properties of each resin. Thus, while the present examples derived from a single type of PDMS, it is understood that other types of resins can be used and selected to meet various use criteria and/or design objectives.

The sensing element layer 14 is made of a flexible conductive film having a very uniform and relatively small thickness compared to the other shapes of the substrate layer that generates an electrical signal when deformed and/or from contact area and/or change in contact area with a sensed object. Preferably, the sensing element layer is made of a conductive conjugated polymer, which generates an electrical signal when deformed and/or contacted by the sensed object. In one embodiment, the sensing element layer is made of Poly(3,4-ethylenedioxythiophene) that can be coated onto the exterior surface 16 of the substrate layer 12 in a highly conformal layer having a substantially constant thickness by means of oxidative chemical vapor deposition; however, other conductive conjugated polymers could be used. In some embodiments, the sensing element layer 14 has a conductivity of at least 3000 S/cm, although other conductivities could be implemented as desired.

In each of the pressure sensors 10 shown in FIGS. 1A-1D, the substrate layer 12 has a substantially flat base portion 20 and a plurality of sensor protrusions 22 projecting upwardly from the upper surface of the base portion. In the embodiment of FIG. 1A, the sensor protrusions 22 are single-scale sensor protrusions 22 that have a protrusion shape with a single scale of size. For example, each of the single-scale sensor protrusions 22 in FIG. 1A has a dome shape that projects upwardly from the upper surface of the base portion 20. The dome shape preferably has a height and diameter (or largest width if not exactly circular/spherical) in millimeter scale, meaning having a diameter and/or height on the order of about 1 mm or a few millimeters. Preferably, the dome shape has a height and/or diameter of about 1 mm to about 10 mm, and more preferably about 1 to about 2 mm. In FIGS. 1B-1D, the sensor protrusions 22 are multiscale sensor protrusions 22 with different portions having at least two different scales of size. In these examples, each multiscale sensor protrusion 22 has a first protrusion 22a with a dome shape in the millimeter scale as described above and a plurality of second protrusions 22b projecting outwardly from the exterior surface of the dome shape. The second protrusions 22b are at a second, much smaller scale size than the first protrusion 22a. In these examples, the second protrusions 22b have generally conical spike shapes that are on the size order of sub-millimeter. In other embodiments, the second protrusions 22b may have generally cylindrical pillar shapes. Preferably, the second protrusions 22b have heights (projecting above the exterior surface of the dome shape) of about 100 micrometers (μm) to about 800 μm (about 0.1 mm to about 0.8 mm), and more preferably about 100 to about 300 μm. The spike-shaped or pillar-shaped second protrusions 22b in some embodiments have a largest diameter of about 50 to about 100 μm. The embodiment in FIG. 1B has a lower density of spike-shaped second protrusions 22b, whereas the embodiment in FIGS. 1C and 1D has a higher density of spike-shaped second protrusions 22b. Thus, the embodiment in FIG. 1B has a dome-shaped first protrusion 22a with low-density spike arrays (DLSA) of the second protrusions 22b, and the embodiment in FIGS. 1C and 1D has a dome-shaped first protrusion 22a with high-density spike arrays (DHSA) of the second protrusions 22b. Although the density and number of the spikes on the DHSA embodiment are larger than the corresponding density and number of spikes on the DLSA embodiment, in all other respects, these two embodiments are otherwise substantially similar.

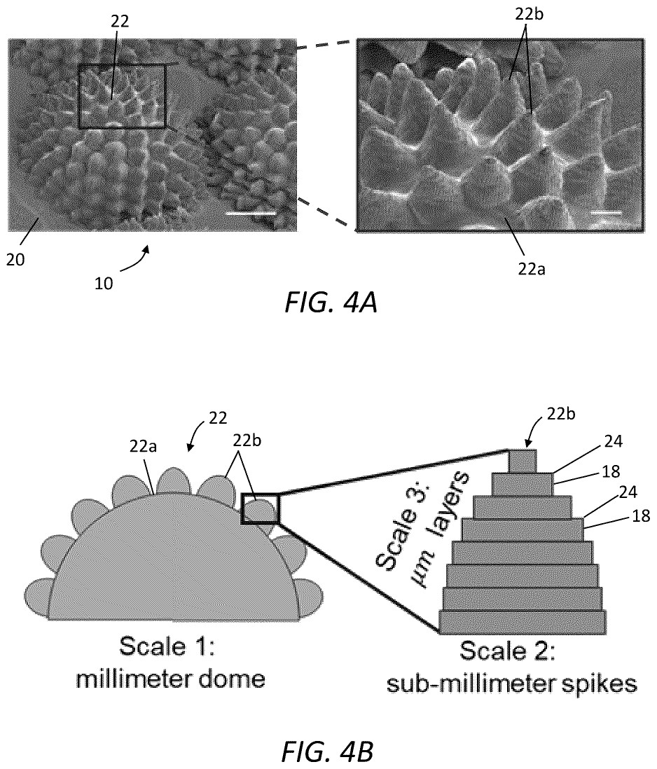

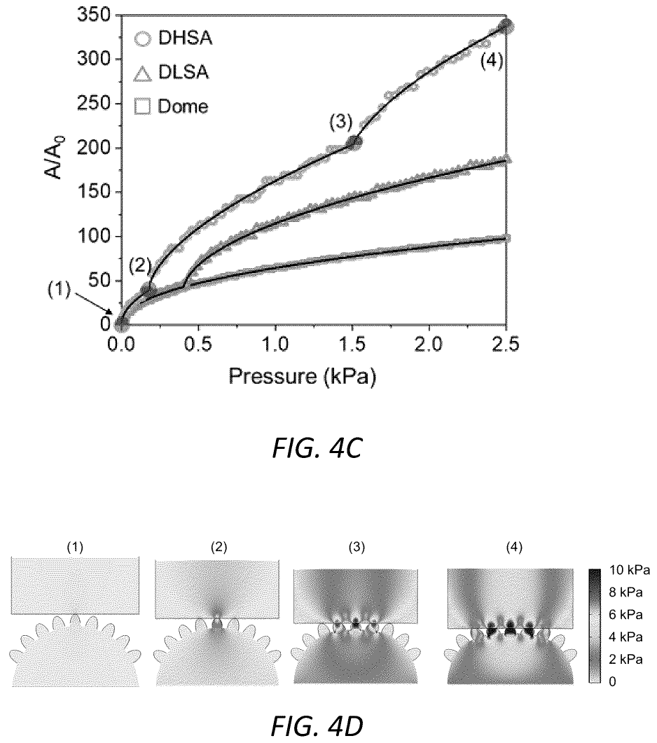

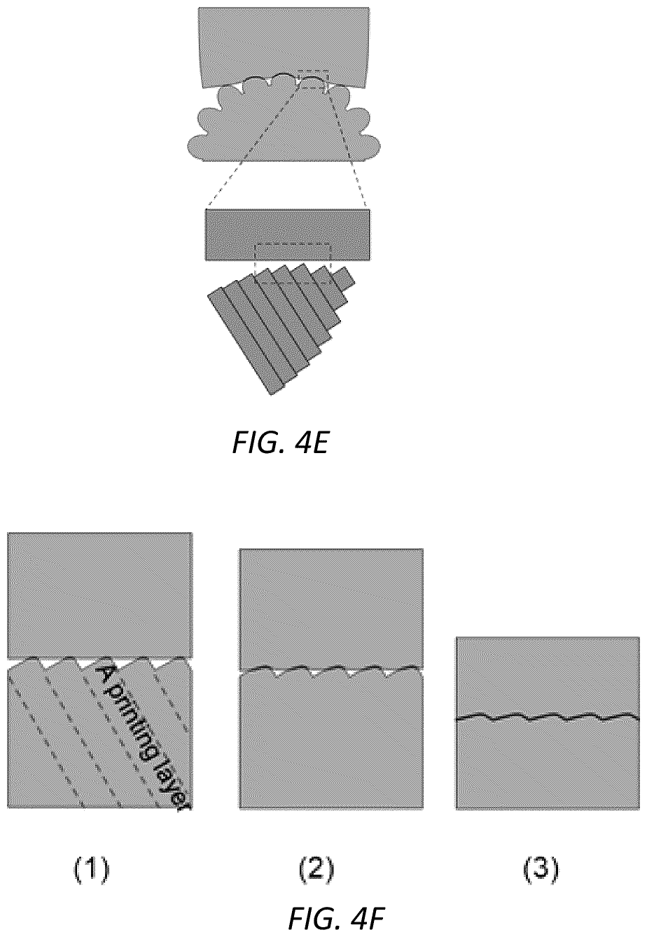

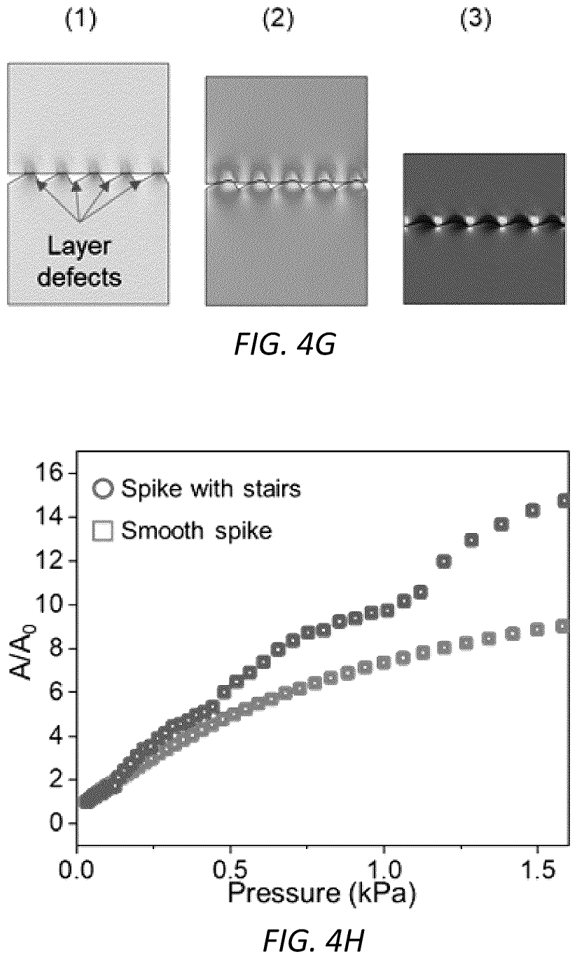

In addition, the 3D printing layers 18 that form the substrate layer 12 preferably also form steps 24 that create stepped edges along the exterior surface of at least the second protrusions 22b due to the planar shapes of the 3D printing layers used to additively build up the overall exterior shape of at the second protrusions 22b, as well as typically the entire shape and volume of the substrate layer 12. In some embodiments, the 3D printing layers have a thickness on the size order of only a few micrometers to at most tens of micrometers. Preferably, each 3D printing layer 18 that collectively forms at least the second projections 22b has a thickness of about 5 to about 50 μm. For example, in some embodiments as best seen in FIG. 4B, the 3D printing layers 18 that form the second projections 22b each have a thickness of about 10 μm, resulting in a stepped exterior surface of the second projections 22b with steps 24 of about 10 μm thickness. Typically, although not necessarily, the entire form of the sensor protrusion 22 is formed by 3D printing layers of about the same size, which results in both the first protrusion 22a and the second protrusion 22b having a similarly stepped outer surface. As explained in detail hereinafter, the implementation of multiscale sensor protrusions 22 having first projections of a first, larger scale size and a second set of projections of a second, smaller scale size projecting from each of the first projections can significantly improve the sensitivity and range of sensitivity of the flexible pressure sensor 10. In addition, the steps 24 formed on the exterior surface of the sensor protrusions 22 are also believed to even further improve the sensitivity and range of sensitivity of the pressure sensor 10, as discussed in further detail below.

The invention is not limited to only the multiscale sensor protrusions 22 or single-scale sensor protrusions 22 illustrated in FIGS. 1C-1D. Rather, in yet other embodiments, the substrate layer 12 could be simply have the morphology of a flat base portion 20 without any additional sensor protrusions. In this embodiment, the sensing element layer 14 would simply be coated onto the flat exterior surface of the base portion. In yet other embodiments, the single-scale sensor protrusions 22 and/or first protrusions 22a of the multiscale sensor protrusions 22 may have other shapes, such as a spike shape or pillar shape. Further, the single-scale or multiscale sensor protrusions 22 and their subcomponents may have other dimensions.

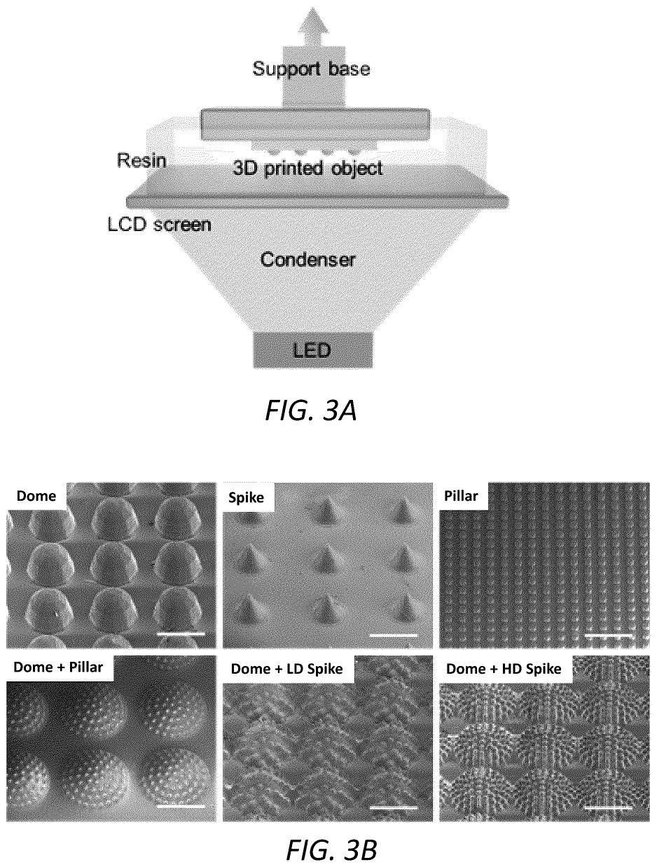

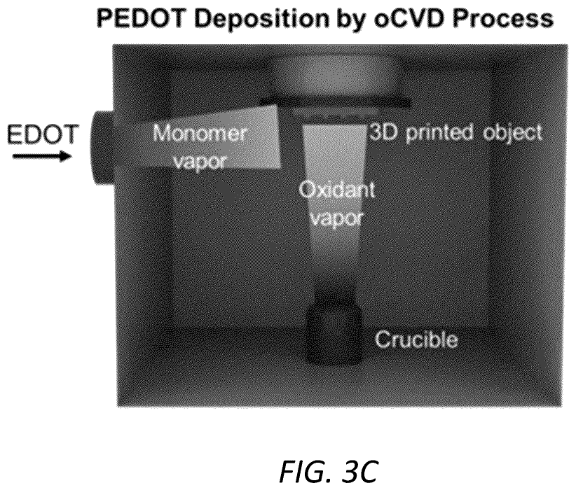

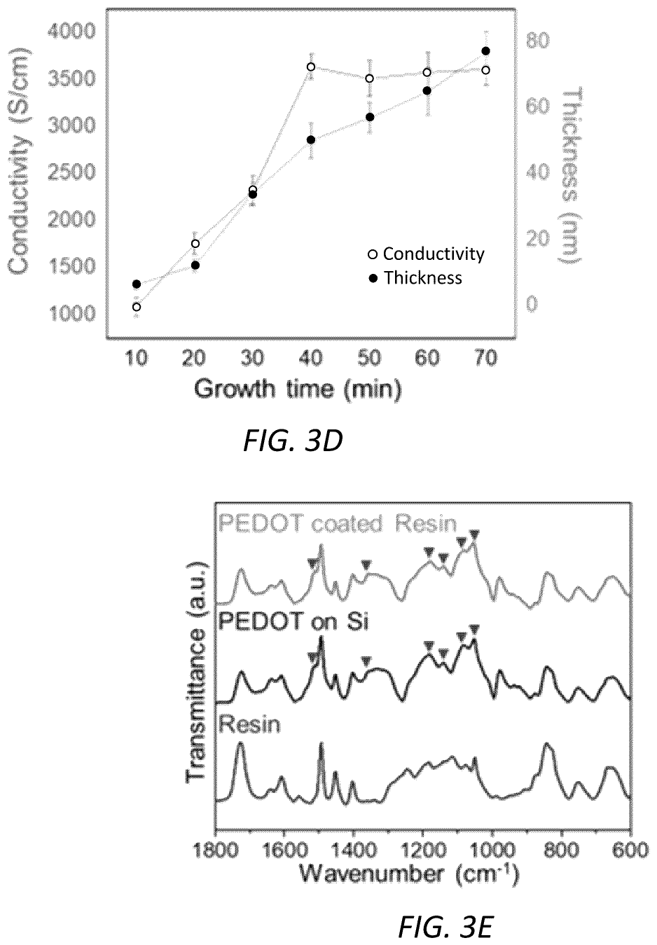

FIGS. 3A-3C illustrate an example process for fabricating the flexible pressure sensor according to some principles of the invention. First, after the desired shape of the substrate layer 12 is modelled into a digital format usable to drive the 3D printer, the substrate layer 12 is printed by additive manufacturing with the 3D printer, which forms a plurality of successive 3D printed layers 18 that collectively define the overall shape and size of the substrate layer. FIG. 3A shows an example of the structure and components of an LCD-based 3D printer that may be used to fabricate microstructured substrates by the 3D printing process. The substrate layer 12 may include high-resolution microstructures, such as a plurality of sensor protrusions 22 extending from a substantially flat exterior surface 16 of the substrate layer. In some examples, an LCD-based VPP technique may be utilized to print high-resolution microstructures. A 3D printing resin may be used to fabricate the flexible patterned platform for pressure sensors formed by the substrate layer 12. In one embedment, the 3D printing resin is made of mixture of 60-63% methacrylate oligomer, 33-36% methacrylate monomers, <3% of 2, 4, 6,-trimethylbenzoyl-diphenyl phosphine oxide, <0.5% color pigments, and <1% 4-methoxyphenol. However, other 3D printing resins could be used. The 3D printing process may be any process suitable for printing to the micrometer to millimeter scale of the structures in the flexible pressure sensor 10. One example suitable 3D printing process is elaborated in the experimental methods section. In validation of the concepts described herein, a photopolymerization resin suitable for pressure sensors was selected for experimentation with a Young's modulus of about 3-5 Mpa similar to PDMS, which is a widely employed flexible substrate for mold-based pressure sensors while photopolymerization reactions were not available.

FIG. 3B displays several 3D-printed substrate layers 12 with sensor protrusions 22 ranging from single-scale protrusions (dome, spike, and pillar) to multiscale protrusions (spikes and pillars on a dome) patterns. The size of the pillars and spikes formed on domes is on the scale of tens of micrometers, which showcases the high-resolution and multiscale capability of the 3D-printing technique used in this study.

Next, the 3D printed substrate layer is conformally coated with a conjugated polymer by oxidative chemical vapor deposition (oCVD) to form a highly conducting sensing element layer 14 covering the exterior surface of the sensor protrusions 22 and the upper exterior surface (as seen in FIG. 2, for example) of the flat base portion 28. FIG. 3C schematically illustrates the oCVD process in a custom-designed reactor. The polymers deposited by the oCVD process are conformally coated on the printed microstructure substrate. A low processing temperature of oCVD (e.g., ≤60° C.) is preferred in order to preserve the 3D-printed substrates 12 without thermal deformation of the microscale patterns (the sensor protrusions 22). The precise thickness controllability and conformality of the oCVD method is of significant importance to make the most use of the multiscale patterns and to achieve seamless coating of oCVD PEDOT as the sensing element. In one embodiment, the thickness of the PEDOT was optimized to about 50 nm, although thinner or thicker coatings of the PEDOT could be used. SEM analysis confirmed that the microstructures on the substrate were well maintained after oCVD PEDOT coating. The thickness and electrical conductivity of the oCVD PEDOT sensing element layer 14 are controlled according to the feedstock of monomer and oxidant, process temperature, and growth time. FIG. 3D shows the thickness and electrical conductivity of oCVD PEDOT films as a function of growth time. The film thickness monotonically increases with the growth time increases, which is the nature of the vapor-phase polymer processing and enables good reproducible thickness controllability. The conductivity of oCVD PEDOT increases as the thickness increases and becomes saturated at a certain thickness (about 50 nm) at which the charge carrier transport is no longer limited by surface scattering. Considering high conductivity of oCVD PEDOT as sensing elements while maintaining the printed patterns, in experiments leading to the present invention, oCVD film with a thickness of 50±5.41 nm and a conductivity of 3,636±131 S/cm was selected for the flexible pressure sensors 10.

In some nonlimiting examples used in investigations leading to the present invention, 3D printing of multi-scale patterned substrate 12 was accomplished as follows. A VPP 3D printer was used to manufacture multiscale-patterned substrates. The three-dimensional CAD model of the microstructured substrates was imported into the CHUTIBOX slicing platform and converted to the corresponding PWMSCTB file format for the printing process. Process parameters such as layer height, exposure time, lifting distance for liquid resin backflow, and lifting speed were specified in the slicing software. High-density and flexible UV LCD-sensitive resin (SuperFlex) was procured from 3D materials Co., Ltd (Korea). All samples were printed with the selected resin and cured at a wavelength of 405 nm.

Also in these investigations, the formation of the flexible sensing element coating 14 through the oCVD process were conducted as follows. oCVD PEDOT films were deposited on 3D printed substrates using a custom-designed CVD reactor. EDOT (97%, Sigma-Aldrich) monomer vapor was injected into the chamber using a needle valve after being heated to 150° C. to vaporize. Iron chloride oxidizing agent (FeCl₃, reagent grade 97%; Sigma-Aldrich), stored in a crucible in the main chamber, was sublimated by heating the crucible to 185° C. at a ramping rate of approximately 6° C./min. The working pressure was maintained as 2×10⁻³ torr through the adjustment of the flow rate of the needle valve. Once both the vaporized monomer and the oxidizing agent were introduced and a consistent chamber pressure was achieved, the deposition was initiated by opening the main shutter that covers the substrate. The substrate was maintained at a constant specified temperature as low as about 60° C., which was optimized to avoid thermal damage to 3D-printed resin substrates. After deposition, the PEDOT-coated samples were rinsed with methanol for 10 min to remove unreacted FeCl₃ and EDOT monomer and dried in a vacuum desiccator to completely evaporate the solvent.

The sensing performance of the mold-free manufactured 3D printed pressure sensors 10 was evaluated. To evaluate figures of merit performance of mold-free manufactured sensors and identify the effect of multiscale microstructures on the sensing characteristics, piezoresistive responses of an example of the flexible sensor (10 mm×10 mm in area) were recorded as a function of multiscale pattern and applied pressure. Several 3D-printed patterns were selected among the structures in FIG. 3B and integrated into pressure sensors. The dome-only array (upper left) consists of domes with a diameter of 1100 μm that are uniformly spaced at 350 μm between domes. The spike arrays (lower middle and lower right) are additionally patterned on the dome-only structures with a spike height and a diameter of 150 and 70 μm, respectively. The 3D models corresponding to each 3D-printed pattern selected are illustrated in FIGS. 1A-1C, corresponding to the mold-free manufactured sensors with a dome only, a dome with low-density spike arrays (DLSA), and a dome with high-density spike arrays (DHSA), respectively. Overall, all three mold-free manufactured sensors show pressure sensor behaviors that increase the amount of current with escalating pressures due to an increase in the contact area between the oCVD-coated microstructure and the conductive metal electrode. However, notable differences are identified among the sensors, depending on the microstructure patterns. Dome-only (single scale) sensors responded to pressures from 0.3 kPa while sensors with multiscale structures (both DLSA and DHSA) can detect pressure as low as 0.07 kPa, which is approximately 10 times lower pressure measurable than that of the dome-only sensor. It is believed that these are the lowest pressure ranges that can be detected among the flexible pressure sensors employing 3D-printed components. In addition, uniform and consistent responses are obtained from multiple measurements at the same pressure applications over a wide range of pressures at both low- and high-pressure regimes. The sequential current response from a low- and high-pressure range obtained from a DHSA sensor showed no hysteresis sensing behaviors between the incremental/decremental pressure applications. This consistent and non-hysteresis performance is possibly attributed to the fast response and recovery capability of the mold-free sensors.

The sensitivity of the flexible pressure sensors 10 were also investigated. The sensitivity(S) a pressure sensor is quantified by S=δ(ΔI/I₀)/δP, where I₀ is the initial current, and ΔI is the current change (%) induced by applying pressure (P), which can be determined by the slope of the plots of ΔI/I₀ versus pressure (P). Like other convention pressure sensors, two linear regimes were identified, a low-pressure regime and a high-pressure regime at about 10 kPa as the variant point. The sensitivity in the low-pressure range (S₁; P<10 kPa) was derived to be about 106.39, 138.12, and 184.82 kPa⁻¹ for the dome, DLSA, and DHSA pressure sensors 10, respectively. The achieved sensitivity from the mold-free manufactured pressure sensors 10 (particularly DHSA) disclosed herein is notable in that most conventional mold-based microstructured sensors (i.e., sensors formed from molds rather than 3D printing) report a sensitivity of less than 100 kPa⁻¹ in the pressure range of 10 kPa. In the high-pressure regime (P>10 kPa), the sensitivity (S₂) of the flexible pressure sensors 10 made by additive manufacturing and oCVD as disclosed herein was found to be 1.91, 2.18, and 2.91 kPa⁻¹ for the dome, DLSA, and DHSA sensors, respectively. Meanwhile, all 3D-printed structures (dome, DLSA, DHSA) of the present disclosure demonstrate broad and high linearity at both low- and high-pressure regimes. In addition, the performance of the mold-free manufactured sensors 10 can be further enhanced through geometry optimization such as the height, diameter, and distribution of the dome and spike array. For example, the height of the dome 22a affects the sensitivity of a dome-only sensor, and tests show that the sensitivity is enhanced with increasing the dome height, and wide range linearity is exhibited. These flexible design capabilities will be instrumental to customize the pattern structures with desired performance in practical applications that require a specific geometry, such as in robots and medical assistive devices. The linearity of sensors is a figure of merit performance of a pressure sensor, which describes how the sensor ideally behaves with varying pressures. Maintaining the linearity in a wide pressure range is desired. The linear regression (R²) of the 3D-printed sensors 10 disclosed herein is similar for all three patterns (dome, DLSA, and DHSA) and as low as 0.965 at both low- and high-pressure regimes, confirming high linearity over a wide pressure range. Two-fold aspects may result in such a high sensitivity in the mold-free manufactured sensors. First, the high electrical conductivity of the sensing element layer 14 oCVD PEDOT facilitates charge transports (i.e., current) that are generated with the change in contact area. The conductivity (3,636±131 S/cm) of oCVD PEDOT optimized for the sensor 10 is significantly higher than other conventional solution-processed conducting polymers (e.g., <900 S/cm). Second, uniquely designed multiscale microstructures 22 in the range from micrometer to millimeter scale may be instrumental to derive the change in contact area and consequently, the current.

Response time is another important sensing performance of the pressure sensors 10. Response time is the time required for the current level to reach 90% of the saturation state under pressure applied, while the time taken to reach 10% of the saturation level after the pressure is removed is defined as recovery time. Testing showed that the DHSA pressure sensor 10 achieved considerably short response (tᵣₑₛ) and recovery (t_{cov}) times (tᵣₑₛ of about 0.038 ms and t_{cov} of about 0.051 ms). These fast response and recovery times, demonstrated from the mold-free manufactured sensors 10 having multiscale sensor protrusions 22, are approximately 100 times faster than those of dome-only sensors (tᵣₑₛ of about 2.41 ms and t_{cov} of about 2.83 ms). With the high conductivity sensing elements, the enhanced response time is further attributed to the multiscale microstructures of the multiscale sensor protrusions 22, leading to much shorter deformation while still generating a larger contact area. As a result, the ultrafast response time of the 3D printed pressure sensors 22 exceeds that of most reported high-performance sensors that were conventionally manufactured from a mold-based technique. The flexible pressure sensors 10 exhibit a comparably fast response time, and are about 100 to about 1000 times faster than most of the conventional sensors consisting of flexible substrates (such as PDMS, PU, and Ecoflex) with metal nanowire or carbon-based nanoelectrodes, which report response times ranging from several ms to several tens of ms. The immediate pressure-induced surface deformation due to the multiscale structures is believed to result in rapid variation of contact area, which was further validated with finite element analysis (FEA) modeling. Testing of the long-term performance stability of the mold-free manufactured pressure sensor also confirmed the uniform response of the sensor to the applied pressure with high stability and reproducibility over an extended measurement duration.

The stress distribution and working mechanisms of the mold-free manufactured flexible pressure sensors 10 were analyzed with FEA modeling. To understand the mechanism for the sensitivity and response/recovery time of the mold-free manufactured sensors, it was simulated how the microstructured substrate featuring multiscale patterns deforms sequentially from micrometer to millimeter scale through the FEA. FIGS. 4A and 4B show the proposed sensor structures with three length scales: millimeter dome (scale 1; about 1 mm), sub-millimeter spikes (scale 2; 110-200 μm), and microscale printing layers (scale 3; about 10 μm). As seen in FIG. 4C, the relative contact area A/A₀ of a single-scale dome only, which is similar to a conventional single-scale sensor, gradually decreases with increasing pressure. However, the A/A₀ of the multiscale sensors is rapidly boosted when an adjacent spike starts to contact the electrode (point (2) and point (3)). The points described as (1)-(4) in FIGS. 4C and 4D represent (1) the initial state, (2) the first spike contact with the electrode, (3) additional adjacent spikes start to contact, and (4) further deformation by applied pressure. FIG. 4D illustrates associated stress distribution images describing how the printed substrate layer 12 progressively deforms and boosts the contact area when increasing the applied pressures with several new spike contacts (i.e., point (2) to (4)) with respect to the initial state (point (1)). The change in the contact area is directly related to the current response (i.e., current flows through the contact area only) and therefore, the change in contact area (ΔA/A₀) is also proportional to the sensitivity (S=δ(ΔI/I₀)/δP). This reveals that by employing more spikes, the sensitivity of the pressure sensors 10 will be consistently boosted without the saturation that is usually observed in conventional sensors (molded sensors with shapes similar to the dome-only sensor). These tests suggest one possible reason why the pressure sensors 10 could maintain a notably high sensitivity (about 184.82 kPa⁻¹) within a large pressure range, compared to the conventional single-scale sensors (2.0 to 151.4 kPa⁻¹) manufactured through molds.

It was further observed that the 3D-printed layers 18 roughen the spikes 22b, surprisingly increasing the contact area. FIGS. 4E-4H illustrate how the printed layer stepping increases the contact area. FIG. 4E shows a spike-shaped second projection 22b is deformed and bent under pressure. As illustrated in FIG. 4F, the surface of a spike also has additional microstructures of the 10 μm-scale stepping edges 24, which is due to the 3D printing layer stepping. When increasing the local pressure between this spike surface and the metal electrode, FIG. 4G shows the progressive deformation of the rough surfaces and stress distributions (from left to right). Specifically, the right side of FIG. 4G exhibits a larger contact surface, indicated by wrinkles due to the presence of stepping edges, as compared to a smooth and flat contact. FIG. 4H verifies that the rough surfaces of a 3D printed spike with layers that form steps 24 on the exterior surface led to more contact area than a smooth spike, when the pressure exceeds 2 kPa. Moreover, a spike with layer stepping yields 57.8% more contact area compared with a smooth spike, when the local pressure exceeds 4 kPa.

The underlying mechanism for ultrafast response time was also investigated. To understand the effect of multiscale microstructures (e.g., the multiscale sensor protrusions 22) on the fast response of the hierarchically patterned pressure sensors 10 disclosed herein, the dynamics of deformation response and recovery were simulated through FEA modeling. The modeling showed that the conventional single-scale sensor leads to a contact mode in which the dome will be volumetrically compacted, and the high-stress area is connected without any low-stress area to expand. Consequently, all the regions with high stress compete and constrain each other's stress release, which significantly elongates the response/recovery time in single-scale sensors. In comparison, the multiscale sensors of the present disclosure generate two new contact modes. In both of these two new contact modes, the spikes are freely bent, and only a small area in the spike has high stress. The high stress is not constrained and can be effectively released to the low-stress area, and hence requires less time to be deformed. In addition, in the case of a multiscale structure, the smaller amount of displacement required to generate the same amount of contact area compared to a single-scale structure also contributes to the fast response time.

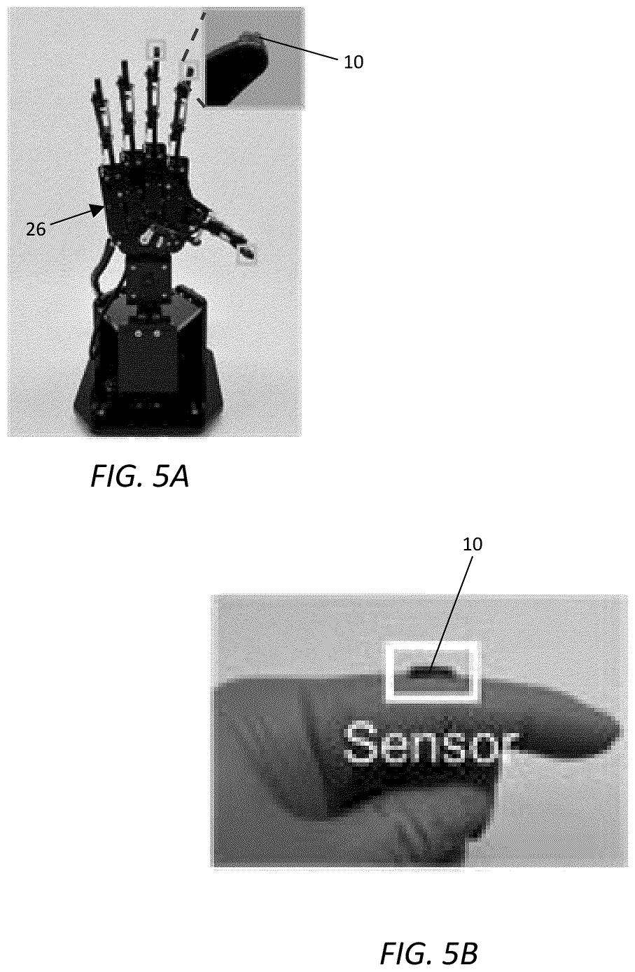

Investigations of the flexible pressure sensors 10 for detection of physical stimuli and tactile sensing applications were also conducted. To demonstrate the practical applicability of the pressure sensors disclosed herein, the sensor was placed on a finger of a robot hand 26 (FIG. 5A). For this investigation, the DHSA pressure sensors 10 were selected for robot object manipulation tests. Tests showed promising detection capability (of robot object manipulation) with clear current responses when each of the three fingers of the robot hand 26 grabs a plastic ball. Since different pressures were generated depending on the size of each finger and contact angles, the current response also varied with the fingers. The thumb and index fingers resulted in a similar current change of 1.7×10⁻⁴ A (i.e., similar pressures are applied to the two fingers) during the demonstration of robot object manipulation while a smaller current of 0.6×10⁻⁴ A was derived from the middle finger. Comparing the recorded current changes from the robot manipulation tests with the sensor performance in other tests, the pressure applied to the fingers could be estimated to 1.5 kPa for the thumb and index fingers and 0.5 kPa for the middle finger. This demonstrated detection capability of the flexible pressure sensors 10 with a real-world robot hand 26 confirms the potential for the flexible pressure sensors 10 to be adopted in advanced robot systems that require high sensitivity and fast response/recovery time.

To further validate the practicability of the flexible sensor 10 manufactured without molds in accordance with the present disclosure, the detection capability of bending signal was evaluated with the sensor attached to a finger joint, as shown in FIG. 5B. The tests showed that the current increases to different levels when the joint bends at five different angles with a short stay. At ambient conditions, the sensor 10 consistently generated current responses with varying finger joint angles that derive deformation of the sensor, which also indicates the high sensitivity of the pressure sensor 10. In addition, the pressure sensor 10 responded well to tiny pressures of 0.07 kPa at a large bending angle of 75° which mimics practical sensor operations for robots and medical assistive devices. To demonstrate the mechanical flexibility of the DHSA pressure sensors 10, bending tests were conducted at different applied pressures. For the bending test, the samples were bent 180° to generate high stress and strain, and their maximum current was measured every cycle. The pressure response was shown to maintain its consistent performance more than 100 bending cycles. The low-pressure detection ability of the pressure sensor 10 was practically evaluated using a tiny item such as an aluminum pellet (130 mg). The pellet, equivalent to a pressure as low as 0.05 kPa, was placed onto and then removed from the pressure sensor 10 to generate a corresponding current response. The mold-free manufactured pressure sensors 10 of the present disclosure responded well to such a small pressure and consistently operated with repeated pellet placement/removal events and the addition of pellets. The flexible pressure sensor 10 exhibited a low detection limit below 0.1 kPa, indicating an improved capability of detecting subtle pressure variation compared with other conventional flexible pressure sensors made by molding. Finally, the sensor's response to repeated touches was investigated in order to verify the fast response of our sensors, which is of particular relevance to acoustic wave detection and urgent healthcare applications. The pressure equivalent to 1 kPa was swiftly contacted and removed at a rate of 2.5 Hz in which the increased contact area by the multiscale structure and the high electrical conductivity of the oCVD PEDOT film results in a fast response with no significant noise levels, further validating the high performance of the mold-free manufactured flexible pressure sensors 10.

The present application discloses a mold-free manufacturing method that integrates two advanced manufacturing techniques of hierarchical 3D printing and vapor-phase conformal coating of flexible conducting polymers. High-resolution 3D printing is leveraged to manufacture the pressure sensor's substrate layer 12 with multiscale patterns across a three-length scale. The multiscale patterns on substrate are then seamlessly coated with a nanoscale sensing element 14, the oCVD PEDOT layer. Much enhanced sensing performance is achieved, which is higher than those manufactured with mold-based techniques, due to the high electrical conductivity of the sensing element, oCVD PEDOT layer 14 and the benefits from the multiscale patterns 22a and 22b. Modeling showed that the enhanced sensitivity is attributed to gradual and sequential increases in contact area in the presence of spikes and layer stepping edges, which synergistically increase the linearity of the sensor in a wide range of pressures. In addition, the modeling also suggests that the fast response time is attributed to the fact that the multiscale structure can produce a large contact area change even with a small pressure variation. Furthermore, the much smaller region stressed (i.e., pressured) in the multiscale structure can generate a faster recovery time, as the stress release is faster than that in a single scale structure where the stress is spread to the entire sensor platform (i.e., dome only). This accounts for the ultra-fast response and recovery time. As a proof of concept, several practical applications are demonstrated for robot object manipulation, detection for bending that mimic actual robot finger operations attached with the sensors 10, and low pressure and fast detection capability. The mold-free manufactured pressure sensors 10 in all these demonstrations provided high sensitivity and fast responses. As a result, it is possible to design and fabricate high-performance pressure sensors for a wide range of desired pressures, which entirely excludes complicated and expensive lithographical procedures and hence provide a large degree of freedom of shapes and patterns of the pressure sensors for real-world applications. The disclosed method of fabrication allows microscale 3D printing to fabricate the flexible multiscale substrates 12 while the oCVD technique coats nanomaterials for functionalities, such as conductivity and sensing.

Next, the experimental methods used in investigations leading to the present invention(s) are described.

To evaluate the performance of the mold-free manufactured pressure sensors 10, after the deposition of PEDOT sensing element layer 14 on the 3D-printed substrates layers 12, two separated silver (Ag) wire electrodes were bonded on the conductive polymer of the sensing element layer. Ag paste and carbon tape were interposed between the wire and polymer films to more tightly fix them and minimize electrical noise. The sensor current responses were recorded using a source meter in a load-cell station at ambient conditions with a bias application of 1 V. Fast response and recovery times of sensors (<1 ms) were evaluated using an NI data acquisition system. A robot hand 26 and fingers (uHandPi Raspberry Pi Robotic Hand, Hiwonder) were used for the object manipulation demonstrations, during which the fingers were wirelessly operated and motioned.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are used herein in the broadest sense, superseding any other implied definitions hereinbefore or hereinafter unless expressly asserted herein to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

While various embodiments have been described, it will be apparent to those of ordinary skill in the art that many more embodiments and implementations are possible. Accordingly, the embodiments described herein are examples, not the only possible embodiments and implementations.

As previously noted above, though the foregoing detailed description describes certain aspects of one or more particular embodiments of the invention, alternatives could be adopted by one skilled in the art. For example, the flexible pressure sensors 10 and their components could differ in appearance and construction from the embodiments described herein and shown in the drawings, functions of certain components of the flexible pressure sensors could be performed by components of different construction but capable of a similar (though not necessarily equivalent) function, and various materials could be used in the fabrication of the flexible pressure sensors and/or their components. As such, and again as was previously noted, it should be understood that the invention is not necessarily limited to any particular embodiment described herein or illustrated in the drawings.

1. A flexible pressure sensor comprising:
a substrate layer comprised of a plurality of 3D printed layers; and
a sensing element layer comprising a conductive conjugated polymer conformally coated on an exterior surface of the substrate layer;
wherein pressure induced deformations of the exterior surface cause detectable changes in electrical current applied across the sensing element layer.

2. The flexible pressure sensor of claim 1, wherein the exterior surface of the substrate layer comprises a plurality of protrusions extending from a substantially flat base surface, wherein heights of the protrusions from the substantially flat base surface are in a range of 10 μm to 1 mm.

3. The flexible pressure sensor of claim 1, wherein the exterior surface of the substrate layer comprises a first plurality of protrusions extending from a substantially flat base surface and a second plurality of protrusions extending from each of the first plurality of protrusions.

4. The flexible pressure sensor of claim 3, wherein each of the first plurality of protrusions has a dome shape.

5. The flexible pressure sensor of claim 4, wherein each of the second plurality of protrusions has at least one of a spike shape and a pillar shape.

6. The flexible pressure sensor of claim 5, wherein each of the second plurality of protrusions comprises a plurality of layers that form stepped edges on the exterior surface of the respective protrusion.

7. The flexible pressure sensor of claim 1, wherein the conductive conjugated polymer is a flexible conductive film synthesized by oxidative chemical vapor deposition.

8. The flexible pressure sensor of claim 7, wherein the conductive conjugated polymer is Poly(3,4-ethylenedioxythiophene).

9. The flexible pressure sensor of claim 1, wherein the conductive conjugated polymer has a conductivity of at least 3000 S/cm.

10. A method of fabricating a flexible pressure sensor, the method comprising:
printing, by additive manufacturing, a substrate layer comprising a plurality of protrusions extending from a base surface; and
conformally coating, by oxidative chemical vapor deposition, the substrate layer with a conjugated polymer.

11. The method of claim 10, wherein the additive manufacturing comprises vat photo-polymerization 3D printing.

12. The method of claim 10, wherein the step of printing comprises printing a second plurality of protrusions on each of the first plurality of protrusions.

13. The method of claim 12, wherein each of the first plurality of protrusions comprises a dome shape.

14. The method of claim 13, wherein each of the second plurality of protrusions comprises at least one of a spike shape and a pillar shape.

15. The method of claim 12, wherein each of the first plurality of protrusions has a size of about 1 mm to about 2 mm.

16. The method of claim 15, wherein each of the second plurality of protrusions has a size of about 100 μm to about 500 μm.

17. The method of claim 10, wherein the conjugated polymer is Poly(3,4-ethylenedioxythiophene).

18. The method of claim 10, wherein the conductivity of the conjugated polymer is at least 3000 S/cm.

19. A robot hand comprising a surface and the flexible pressure sensor of claim 1 mounted to the surface.
